(19) United States
(12) Patent Application Publication
(10) Pub. No.: US 2026/0154715 A1
(43) Pub. Date: Jun. 4, 2026

(54) COMPUTER-IMPLEMENTED METHOD AND SYSTEM FOR DETERMINING A SET OF PARAMETERS FOR DEVELOPING AN OIL AND GAS FIELD OR INFRASTRUCTURE

(71) Applicant: PETROLIAM NASIONAL BERHAD (PETRONAS), Kuala Lumpur (MY)

(72) Inventors: Saiful Azuan ABDUL AZIZ, Kuala Lumpur (MY); Grant Albert VEROBA, Kuala Lumpur (MY); Nurul Aminah MOHD AZMI, Kuala Lumpur (MY); Muhammad Aizuddin ZAINAL ABIDIN, Kuala Lumpur (MY); Khaidir ARIFFIN, Kuala Lumpur (MY); Mashitah MD JAIS, Kuala Lumpur (MY); Fariz Shahfizal JAMEAN, Kuala Lumpur (MY); M Syafiq ABDULLAH, Kuala Lumpur (MY)

(21) Appl. No.: 19/123,932

(22) PCT Filed: Oct. 21, 2023
(86) PCT No.: PCT/MY2023/050084

§ 371 Date: Apr. 24, 2025

(30) Foreign Application Priority Data
Oct. 28, 2022 (MY) PI2022006052

(51) Int. Cl. G06Q 30/0283; G06Q 10/0637; G06Q 50/06

(52) U.S. Cl. CPC G06Q 30/0283; G06Q 10/0637; G06Q 50/06

(57) ABSTRACT

A computer implemented method for determining a set of parameters for developing an oil and gas field or infrastructure is described. In an embodiment, the method comprises: (i) receiving a plurality of input parameters comprising a type of the oil and gas field or infrastructure, a stage parameter indicating a stage of the oil and gas field or infrastructure, a type of output of the oil and gas field or infrastructure and a location of the oil and gas field or infrastructure: (ii) receiving historical data associated with the plurality of input parameters: (iii) generating sets of suggested parameters for developing the oil and gas field or infrastructure based on the plurality of input parameters and the historical data, each of the sets of suggested parameters includes development parameters: (iv) forming a subset of the sets of suggested parameters based on at least one of the development parameters; and (v) determining a cost estimate for each of the subset of the sets of suggested parameters for use in determining the set of parameters for developing the oil and gas field or infrastructure. A system for determining a set of parameters for developing an oil and gas field or infrastructure is also described.

### TECHNICAL FIELD

The present disclosure relates to a computer-implemented method and system for determining a set of parameters for developing an oil and gas field or infrastructure.

### BACKGROUND

Substantial investments are required to develop an oil and gas development, such as an oil and gas field and/or an oil and gas infrastructure, within the oil and gas industry. It is therefore important to adopt appropriate methods and/or processes to ensure an economic viability of such development, to improve quality and output, and to mitigate any potential risks.

Existing methods for assessing and evaluating oil and gas development parameters are highly manual. This results in poor time and tool management, a long lead-time and a high resource requirement to complete such front-end work, thereby increasing opportunity costs and wastages. Further, such manual front-end processes typically occur independently within a larger oil and gas field and infrastructure development framework. Consequently, the massive amount of data required in relation to these front-end processes are dispersed across different domains. The lack of coordination between different domains within the larger development framework causes poorer decision making, resulting in sub-optimal solutions, delivery time and value generation. It is also difficult to efficiently access benchmarking data which is important to ensure the quality and value of an oil and gas development. In addition, manual data handling from multiple independent data sources increases a risk of human error and inconsistent data entry.

It is therefore desirable to provide a computer-implemented method and system for determining a set of parameters for developing an oil and gas field or infrastructure which address the aforementioned problems and/or provides a useful alternative. Further, other desirable features and characteristics will become apparent from the subsequent detailed description and the appended claims, taken in conjunction with the accompanying drawings and this background of the disclosure.

### SUMMARY

Aspects of the present application relate to a computer-implemented method and system for determining a set of parameters for developing an oil and gas field or infrastructure.

In accordance with a first aspect, there is provided a computer implemented method for determining a set of parameters for developing an oil and gas field or infrastructure, the method comprises: (i) receiving a plurality of input parameters comprising a type of the oil and gas field or infrastructure, a stage parameter indicating a stage of the oil and gas field or infrastructure, a type of output of the oil and gas field or infrastructure, and a location of the oil and gas field or infrastructure; (ii) receiving historical data associated with the plurality of input parameters; (iii) generating sets of suggested parameters for developing the oil and gas field or infrastructure based on the plurality of input parameters and the historical data, each of the sets of suggested parameters includes development parameters; (iv) forming a subset of the sets of suggested parameters based on at least one of the development parameters; and (iv) determining a cost estimate for each of the subset of the sets of suggested parameters for use in determining the set of parameters for developing the oil and gas field or infrastructure.

By incorporating the steps of (iii) generating sets of suggested parameters based on the plurality of input parameters and the historical data, (iv) forming the subset of the sets of suggested parameters and (v) determining a cost estimate for each of the sets of suggested parameters, the aforementioned computer-implemented method (a) generates a wide range of potential sets of parameters for developing an oil and gas field or infrastructure with little or no human intervention and (b) provides a common benchmark for ranking and forming a subset of these potential sets of parameters (or sets of suggested parameters) based on at least one of the development parameters. The use of a common benchmark provides a standardised selection process and improves a selection of the subset of the sets of suggested parameters for developing an oil and gas field or infrastructure. In an embodiment, the computer-implemented method provides a common platform for integrating technical and cost requirements in generating and forming the subset of the sets of suggested parameters, thereby improving technical and cost accuracies in determining a set of parameters for an oil and gas field or infrastructure. As a result of the integration of technical and cost requirements, eventual sets of parameters for use in developing oil and gas fields or infrastructures are generated and determined based on similar sources of data, thereby providing consistency across a wider framework for field development initiatives for developing oil and gas fields or infrastructures. Further, the computer-implemented method for determining a set of parameters for developing an oil and gas field or infrastructure provides a centralised platform for integrating use of external databases and project learnings, thereby improving an overall performance for determining a set of parameters for developing an oil and gas field or infrastructure. The integrated use of databases in a centralised way also provides an efficient way of benchmarking processes across the oil and gas industry as a whole.

The method may comprise: assigning weightages to at least some of the development parameters; calculating a score for each of the sets of suggested parameters based on the weightages; and determining at least some of the sets of suggested parameters to be excluded from forming the subset of the sets of suggested parameters to form a remaining portion of the sets of suggested parameters, the at least some of the sets of suggested parameters are determined to be excluded if their scores are below a predetermined score value.

The plurality of input parameters may include a desired cost parameter and the development parameters may include an estimated cost parameter. The method may comprise: determining, for each of the remaining portion of the sets of suggested parameters, if the estimated cost parameter is within a predetermined range of the desired cost parameter; and selecting part of the remaining portion of the sets of suggested parameters for forming the subset of the sets of suggested parameters, the part of the remaining portion of the sets of suggested parameters are selected if their estimated cost parameter is within a predetermined range of the desired cost parameter.

The method may comprise: generating an estimated cost plot using historical cost data associated with one of the development parameters; and determining the cost estimate using the estimated cost plot and a corresponding development parameter of each of the subset of the sets of suggested parameters.

The method may comprise: receiving, from an empirical data server, empirical data associated with the oil and gas field or infrastructure; and generating the sets of suggested parameters based on the empirical data.

The method may comprise: receiving implementation results of the determined set of parameters; and transmitting the implementation results to a database for storage, the implementation results being used to update the historical data associated with the input parameters for determination of subsequent sets of parameters for developing subsequent oil and gas fields or infrastructures.

The method may comprise: transmitting, to a user device, the subset of the sets of suggested parameters for verification of their development parameters; and receiving, from the user device, verified development parameters for each of the subset of the sets of suggested parameters.

The method may comprise: transmitting, to a user device, the cost estimate of each of the subset of the sets of suggested parameters for verification; and receiving, from the user device, a verified cost estimate for each of the subset of the sets of suggested parameters.

In accordance with a second aspect, there is provided a computer readable medium storing processor executable instructions which when executed on a processor cause the processor to carry out any of the preceding method.

In accordance with a third aspect, there is provided a system for determining a set of parameters for developing an oil and gas field or infrastructure, the system comprising a processor and a data storing computer program instructions operable to cause the processor to: receive a plurality of input parameters comprising a type of the oil and gas field or infrastructure, a stage parameter indicating a stage of the oil and gas field or infrastructure, a type of output of the oil and gas field or infrastructure, and a location of the oil and gas field or infrastructure; receive historical data associated with the plurality of input parameters; generate a set of suggested parameters for developing the oil and gas field or infrastructure based on the plurality of input parameters and the historical data, each of the sets of suggested parameters includes development parameters; form a subset of the sets of suggested parameters based on at least one of the development parameters; and determine a cost estimate for each of the subset of the sets of suggested parameters for use in determining the set of parameters for developing the oil and gas field or infrastructure.

The data storage may store computer program instructions operable to cause the processor to: assign weightages to at least some of the development parameters; calculate a score for each of the sets of suggested processes based on the weightages, and determine at least some of the sets of suggested parameters to be excluded from forming the subset of the sets of suggested parameters to form a remaining portion of the sets of suggested processes, the at least some of the sets of suggested parameters are determined to be excluded if their scores are below a predetermined score value.

The plurality of input parameters may include a desired cost parameter and the development parameters may include an estimated cost parameter. The data storage may store computer program instructions operable to cause the processor to: determine, for each of the remaining portion of the sets of suggested parameters, if the estimated cost parameter is within a predetermined range of the desired cost parameter; and select part of the remaining portion of the sets of suggested parameters for forming the subset of the sets of suggested parameters, the part of the remaining portion of the sets of suggested parameters are selected if their estimated cost parameter is within a predetermined range of the desired cost parameter.

The data storage may store computer program instructions operable to cause the processor to: generate an estimated cost plot using historical cost data associated with one of the development parameters; and determine the cost estimate using the estimated cost plot and a corresponding development parameter of each of the subset of the sets of suggested parameters.

The type of the oil and gas field or infrastructure may be selected from one of: an upstream oil and gas field or infrastructure, a mid-stream oil and gas field or infrastructure and a downstream oil and gas field or infrastructure.

The stage parameter may include one of: greenfield, infill development and brownfield.

The data storage may store computer program instructions operable to cause the processor to: receive, from an empirical data server, empirical data associated with the location of the oil and gas field or infrastructure; and generate the sets of suggested parameters based on the empirical data.

The development parameters may comprise one or more of: a processing design requirement parameter, a facility sizing parameter, a power requirement parameter, a structural requirement parameter and a piping requirement parameter.

The historical data associated with the plurality of input parameters may include empirical environmental data and past infrastructure data associated with the location of the oil and gas field or infrastructure.

The data storage may store computer program instructions operable to cause the processor to: receive implementation results of the determined set of parameters; and transmit the implementation results to a database for storage, the implementation results being used to update the historical data associated with the input parameters for determination of subsequent sets of parameters for developing subsequent oil and field fields or infrastructures.

The data storage may store computer program instructions operable to cause the processor to: transmit, to a user device, the subset of the sets of suggested parameters for verification of their development parameters; and receive, from the user device, verified development parameters for each of the subset of the sets of suggested parameters.

The data storage may store computer program instructions operable to cause the processor to: transmit, to a user device, the cost estimate of each of the subset of the sets of suggested parameters for verification; and receive, from the user device, a verified cost estimate for each of the subset of the sets of suggested parameters.

The plurality of input parameters may comprise a front-end loading (FEL) stage, the FEL stage being selected from one of: Pre-FEL, FEL 1, FEL 2 and FEL 3

It should be appreciated that features relating to one aspect may be applicable to the other aspects. Embodiments therefore provide a computer-implemented method and system for determining a set of parameters for developing an oil and gas field or infrastructure. By incorporating the aforementioned steps (iii), (iv) and (v), the aforementioned computer-implemented method and system are configured to (a) generate a wide range of potential sets of parameters for use in developing an oil and gas field or infrastructure using the provided input parameters with little or no human intervention and (b) provide a common benchmark for ranking and selecting the subset of the sets of suggested parameters based on at least one of the development parameters. The use of a common benchmark provides a standardised selection process and improves a selection accuracy for forming the subset of the sets of suggested parameters for developing an oil and gas field or infrastructure. The computer-implemented method and system also provide a common platform for integrating technical and cost requirements in forming the subset of the sets of suggested parameters, thereby improving technical and cost accuracies in determining a set of parameters for developing an oil and gas field or infrastructure. As a result of the integration of technical and cost requirements, the set of parameters (e.g. an optimal/eventual set of parameters) for use in developing an oil and gas field or infrastructure is generated and determined based on structured sources of data, calculation methods and similar benchmarks, thereby providing consistency across a wider framework for field development initiative for oil and gas fields or infrastructures. Further, the aforementioned computer-implemented method and system provide a centralised platform for integrating use of different databases and project learnings, thereby improving an overall performance for determining a set of parameters for developing oil and gas fields or infrastructures. The integrated use of various databases also provides an efficient way of benchmarking processes across the oil and gas industry and provides a holistic and accurate approach in determining a set of parameters for use in developing an oil and gas field or infrastructure.

### BRIEF DESCRIPTION OF THE DRAWINGS

Embodiments will now be described, by way of example only, with reference to the following drawings, in which:

FIG. 1 shows a schematic of a computer network for determining a set of parameters for developing an oil and gas field or infrastructure in accordance with an embodiment;

FIG. 2 shows a block diagram of a computer system forming part of the computer network of FIG. 1 for determining a set of parameters for developing an oil and gas field or infrastructure in accordance with an embodiment;

FIG. 3 is a flowchart showing steps of a method for determining a set of parameters for developing an oil and gas field or infrastructure in accordance with an embodiment;

FIG. 4 is a flowchart showing steps of a method for determining at least some of the sets of suggested parameters to be excluded from forming the subset of the sets of suggested parameters of FIG. 3 in accordance with an embodiment;

FIG. 5 is a flowchart showing steps of a method for selecting a portion of the sets of suggested parameters for forming the subset of the sets of suggested parameters of FIG. 3 in accordance with an embodiment;

FIG. 6 is a flowchart showing steps of a method for determining a cost estimate for each of the sets of suggested parameters of FIG. 3 in accordance with an embodiment;

FIG. 7 shows steps of a method for determining a set of parameters for developing an oil and gas field or infrastructure in accordance with an embodiment;

FIG. 8 shows an illustration of a user interface for providing input parameters in relation to development information to the computer system of FIG. 2 in accordance with an embodiment;

FIG. 9 shows an illustration of a user interface for providing input parameters in relation to fields data to the computer system of FIG. 2 in accordance with an embodiment;

FIG. 10 shows an illustration of a user interface for providing input parameters in relation to infrastructure data to the computer system of FIG. 2 in accordance with an embodiment;

FIG. 11 shows an illustration of a user interface for providing input parameters in relation to environmental data to the computer system of FIG. 2 in accordance with an embodiment;

FIG. 12 shows an illustration of a user interface for providing input parameters in relation to wells costs to the computer system of FIG. 2 in accordance with an embodiment;

FIG. 13 shows an illustration of a user interface during generation of suggested sets of parameters for determining a set of parameters for developing an oil and gas field or infrastructure as well as the cost estimation in accordance with an embodiment;

FIG. 14 shows an illustration of a user interface where suggested sets of parameters are ranked according to different development parameters, in accordance with an embodiment;

FIG. 15 shows an illustration of a user interface for analysing the suggested sets of parameters according to a predetermined range of a development parameter, in accordance with an embodiment;

FIG. 16 shows an illustration of a user interface of a summary page including a subset of the sets of suggested parameters in accordance with an embodiment;

FIG. 17 shows an illustration of a user interface for benchmarking the subset of the sets of suggested parameters of FIG. 16 in relation to their estimated costs in accordance with an embodiment; and

FIG. 18 shows an illustration of a user interface of a summary of the results after performing the computer-implemented method for determining a set of parameters for developing an oil and gas field or infrastructure in accordance with an embodiment.

### DETAILED DESCRIPTION

Exemplary embodiments relate to a computer-implemented method and system for determining a set of parameters for developing an oil and gas field or infrastructure. An oil and gas field or infrastructure may also generally be referred to as an oil and gas development. Although the following description refers to developing an oil and gas field or infrastructure, it should be appreciated that a plurality of sets of parameters for developing a plurality of oil and gas fields or infrastructures can be developed using a same method and/or system.

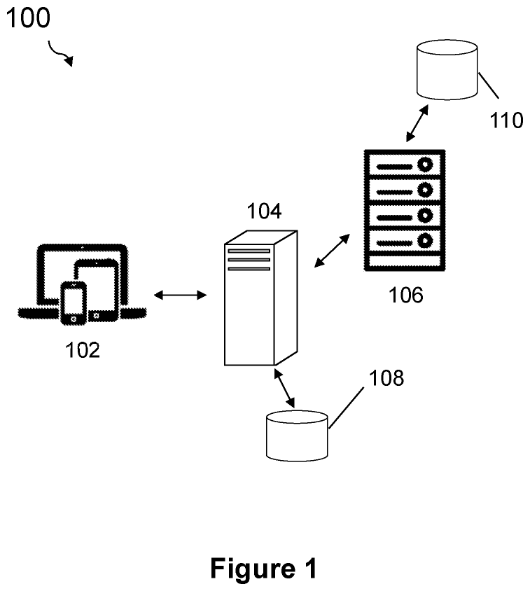

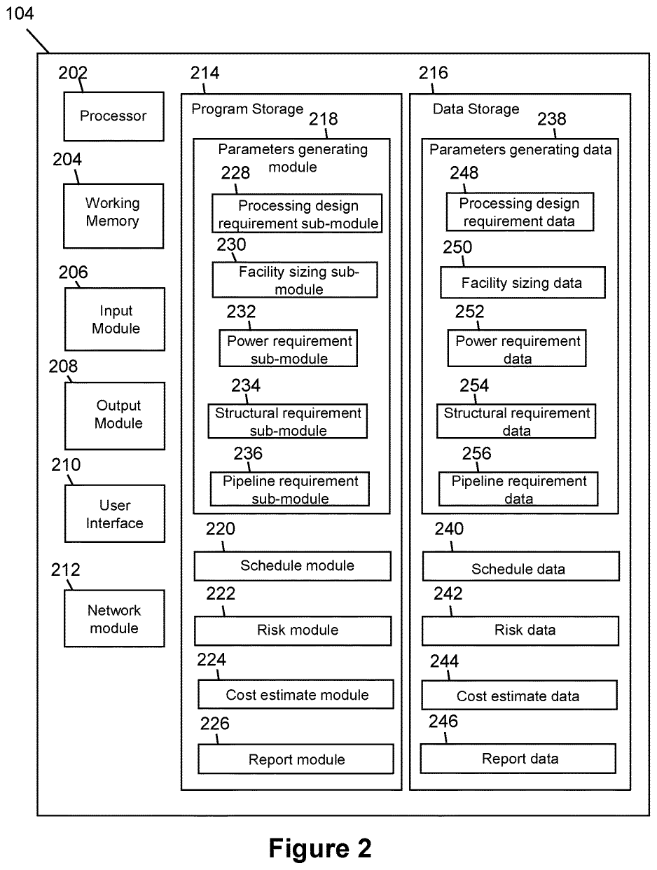

FIG. 1 shows a computer network 100 for determining a set of parameters for developing an oil and gas field or infrastructure in accordance with an embodiment. The computer network 100 comprises a computer system 104 which includes a processor and a data storage storing computer program instructions operable to cause the processor to perform methods for determining the set of parameters (e.g. an optimal set of parameters) for developing oil and gas field or infrastructure. Details of the computer system 104 are described in relation to FIG. 2 below. The computer system 104 is in communication with a user device 102 and an external server 106. The user device 102 is any electronic device which enables the user to access the computer system 104 for performing at least the methods for determining the set of parameters for developing an oil and gas field or infrastructure. The user electronic device 102 may be a mobile phone, a laptop/notebook, a desktop, a tablet, a personal digital assistant (PDA), and/or a computer. The external server 106 may be associated with a wider framework of field development initiatives use in developing a set of parameters for developing an oil and gas field or infrastructure, or associated with an internal service provider and/or an external service provider for providing technical and/or cost benchmarking assessments. The internal and/or external benchmarking assessments allow real time comparison with the cost estimates generated by the computer system 104 and provide optimization opportunities based on deviations to these benchmark assessments which may impact the eventual set of parameters determined for use in developing the oil and gas field or infrastructure. Moreover, a database 108 is operationally connected to the computer system 104. The database 108 serves at least to store data related to determining a set of parameters for developing an oil and gas field or infrastructure. The data comprises input parameters and historical data associated with the input parameters, and data associated with each modules of the computer system 104 as illustrated in FIG. 2 below. In addition, an external database 110 is operationally connected to the external server 106. The external database 110 is configured to store data associated with technical and/or cost benchmarking. Although the database 108 and the external database 110 are shown as external databases in FIG. 1, these databases 108, 110 may also form part of the computer system 104 and the external server 106 respectively. Further, although only one user device 102, one database 108, one external server 106 and one external database 110 are shown in FIG. 1, it is envisaged that a plurality of user device 102, a plurality of databases 108 and a plurality of external servers 106 may be operationally connected to the computer system 104. A plurality of external bases 110 may also be operationally connected to one or more external servers 106.

FIG. 2 shows a block diagram of the computer system 104 for determining a set of parameters for developing an oil and gas field or infrastructure in accordance with an embodiment.

As shown in FIG. 2, the computer system 104 includes memory that stores computer program modules which implement computer-implemented methods for determining a set of parameters for developing an oil and gas field or infrastructure. The computer system 104 comprises a processor 202, a working memory 204, an input module 206, an output module 208, a user interface 210, a network module 212, a program storage 214 and data storage 216. The processor 202 may be implemented as one or more central processing unit (CPU) chips or “brains” for the computer-implemented methods. The program storage 214 is a non-volatile storage device such as a hard disk drive which stores computer program modules such as a parameters generating module 218, a schedule module 220, a risk module 222, a cost estimate module 224 and a report module 226. In an embodiment, the computer program modules can be stored in a cloud storage. The computer program modules are loaded into the working memory 204 for execution by the processor 202. The working memory 204 includes read only memory (ROM) and random-access memory (RAM) for executing the computer program modules. The input module 206 is an interface which allows data, for example input parameters for use in determining the set of parameters for developing the oil and gas field or infrastructure, to be received by the computer system 104. The output module 208 is an output device which allows data and results generated in relation to determining the set of parameters for developing the oil and gas field or infrastructure by the computer system 104 to be output. The output module 208 may be coupled to a display device or a printer. The user interface 210 allows a user of the computer system 104 to input selections and commands and may be implemented as a graphical user interface. The network module 212 enables the processor 202 to communicate with the Internet or one or more intranets. With such a system connection, it is contemplated that the processor 202 receives information within the computer network 100, or might output information to the computer network 100 in the course of performing computer-implemented methods in relation to determining the set of parameters for developing the oil and gas field or infrastructure. The data storage 216 stores data in relation to the computer program modules 218, 220, 222, 224, 226. Although the data storage 216 is shown to reside within the computer system 104, in an embodiment, the data storage 216 can also resides external to the computer system 104, for example at the database 108.

The program storage 214 stores the parameters generating module 218, the schedule module 220, the risk module 222, the cost estimate module 224 and the report module 226. The parameters generating module 218 comprises sub-modules including a processing design requirement sub-module 228, a facility sizing sub-module 230, a power requirement sub-module 232, a structural requirement sub-module 234 and a pipeline requirement sub-module 236. The parameters generating module 218 together with its sub-modules 228, 230, 232, 234, 236, the schedule module 220, the risk module 222, the cost estimate module 224 and the report module 226 cause the processor 202 to execute various computer-implemented methods which are described in more detail below. The program storage 214 may be referred to in some contexts as computer readable storage media and/or non-transitory computer readable media. As depicted in FIG. 2, the computer program modules 218, 220, 222, 224, 226 and sub-modules 228, 230, 232, 234, 236 are distinct modules which perform respective functions implemented by the computer system 104. It will be appreciated that the boundaries between these modules are exemplary only, and that alternative embodiments may merge modules or impose an alternative decomposition of functionality of modules. For example, the modules discussed herein may be decomposed into sub-modules to be executed as multiple computer processes, and, optionally, on multiple computers. Moreover, alternative embodiments may combine multiple instances of a particular module or sub-module. It will also be appreciated that, while a software implementation of the computer program modules is described herein, these may alternatively be implemented as one or more hardware modules (such as field-programmable gate array(s) or application-specific integrated circuit(s)) comprising circuitry which implements equivalent functionality to that implemented in software.

The data storage 216 stores various data and parameters. As shown in FIG. 2, the data storage 216 has storage in relation to parameters generating data 238, schedule data 240, risk data 242, cost estimate data 244 and report data 246 for use with their corresponding modules 218, 220, 222, 224, 226. The parameters generating data 238 can be sub-categorized into processing design requirement data 248, facility sizing data 250, power requirement data 252, structural requirement data 254 and pipeline requirement data 256 for use with their corresponding sub-modules 228, 230, 232, 234, 236. Data, for example a plurality of input parameters, entered by the user in relation to determining the set of parameters for developing the oil and gas field or infrastructure is stored as parameters generating data 238. The parameters generating data 238 can also include historical data associated with the plurality of input parameters. The relevant data from these input parameters are used by the parameters generating module 218 for generating sets of suggested parameters. For example, an input parameter in relation to a type of output of the oil and gas field or infrastructure is used by the processing design requirement sub-module 228 and any output from the processing design requirement sub-module 228 can be stored as the processing design requirement data 248. The sub-category of data 248, 250, 252, 254, 256 can therefore include data (including inputs and/or outputs) relevant for use with their respective sub-modules 228, 230, 232, 234, 236. The schedule data 240 includes data in relation to schedules generated by the schedule module 220 for sets of the suggested parameters. The risk data 242 includes model data and/or historical data relevant for use with the risk module 222 to perform a cost risk analysis associated with the different costs of each of the sets of suggested parameters (e.g. CAPEX, OPEX, Constructions years, number of wells etc.) for determining uncertainties and risks associated with these different costs. The cost estimate data 244 includes current and/or historical cost data associated with at least one of the development parameters of a set of the suggested parameters, and can be used for generating an estimated cost plot for determining a cost estimate of each of the subset of the sets of suggested parameters. The report data 246 includes data associated with summary reports generated by the report module 226, and data in relation to a progress in developing the oil and gas field or infrastructure using the determined set of parameters.

Although the technical architecture is described with reference to a computer system 104, it should be appreciated that the technical architecture may be formed by two or more computers in communication with each other that collaborate to perform a task. For example, but not by way of limitation, an application may be partitioned in such a way as to permit concurrent and/or parallel processing of the instructions of the application. Alternatively, the data processed by a computer program module may be partitioned in such a way as to permit concurrent and/or parallel processing of different portions of a data set by the two or more computers. In an embodiment, virtualization software may be employed by the technical architecture to provide the functionality of a number of servers that is not directly bound to the number of computers in the technical architecture. In an embodiment, the functionality disclosed above may be provided by executing a computer program module or computer program modules in a cloud computing environment. Cloud computing may comprise providing computing services via a system connection using dynamically scalable computing resources. A cloud computing environment may be established by an enterprise and/or may be hired on an as-needed basis from a third-party provider.

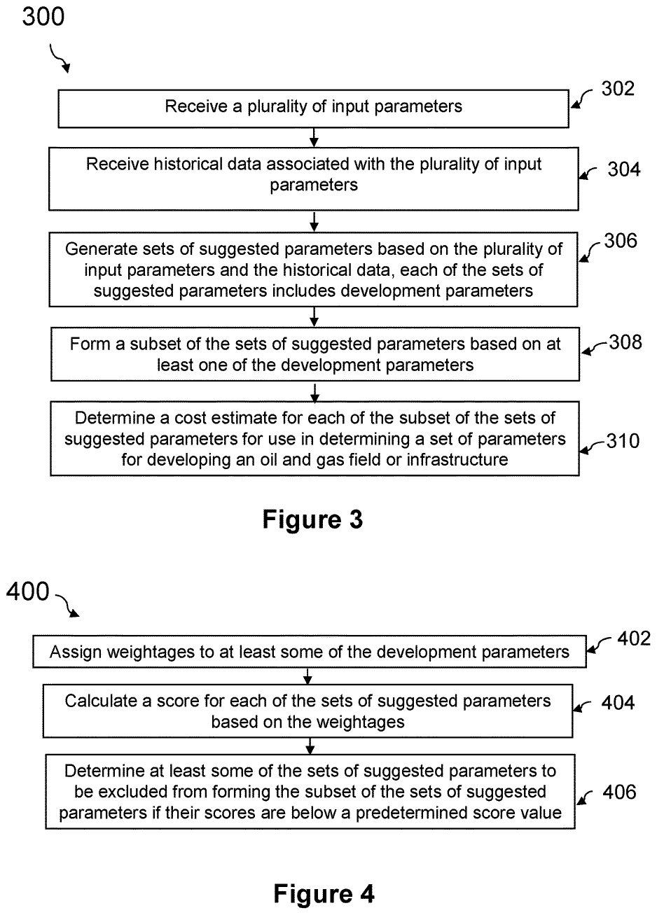

FIG. 3 is a flowchart showing steps of a method 300 for determining a set of parameters for developing an oil and gas field or infrastructure in accordance with an embodiment. The method 300 is carried out on the computer system 104.

In a step 302, the parameters generating module 218 is executed by the processor 202 to receive a plurality of input parameters. The plurality of input parameters is received via the input module 206, or via the network module 212 if the plurality of input parameters is provided by the user device 102 via a network (e.g. internet or intranet). The plurality of input parameters comprises a type of the oil and gas field or infrastructure, a stage parameter indicating a stage of the oil and gas field or infrastructure, a type of output of the oil and gas field or infrastructure and a location of the oil and gas field or infrastructure.

A type of the oil and gas field or infrastructure relates to a type of oil and gas field and/or infrastructure development which the user would like to engage. In the present embodiment, the type of the oil and gas field or infrastructure can be selected from one of: an upstream oil and gas field or infrastructure, a mid-stream oil and gas field or infrastructure and a downstream oil and gas field or infrastructure. An upstream oil and gas field or infrastructure includes exploration and production operations for oil and gas fields and infrastructure development, such as searching for potential underground crude oil and natural gas fields, drilling of wells, operating the wells to recover and bring the crude oil or raw natural gas to the surface. A mid-stream oil and gas field or infrastructure involves transportation (e.g. via pipelines), storage, and marketing of crude or refined petroleum products. A downstream oil and gas field or infrastructure involves, for example, the refining of petroleum crude oil and the processing and purifying of raw natural gas, and distribution of products derived from crude oil and natural gas.

A stage parameter may include one of: greenfield, in-fill development and brownfield. If the stage parameter is greenfield, it relates to a field for an oil and gas field or infrastructure which is new and does not impose any constraints in determining a set of parameters for developing the oil and gas field or infrastructure. If the stage parameter is in-fill development, it relates to a field for an oil and gas field or infrastructure which is partially developed and includes some infrastructures but is otherwise unused and/or underutilized. If the stage parameter is brownfield, it relates to a field for an oil and gas field or infrastructure which has been developed with existing infrastructures. The stage parameter therefore relates to a stage of the oil and gas field or infrastructure, and may affect the time and costs for developing an oil and gas field or infrastructure. The stage parameter may also be defined differently by a skilled person in the art, for example, by including additional stages or sub-stages.

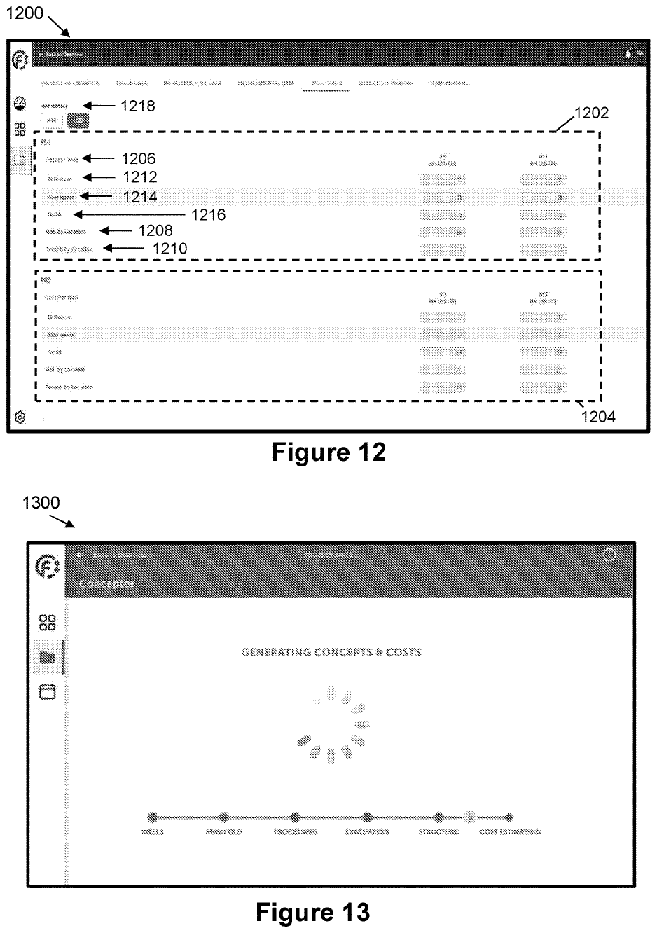

A type of output of the oil and gas field or infrastructure may include one of: oil, gas, oil and gas, condensate and liquified petroleum gas (LPG). A location of the oil and gas field or infrastructure relates to a location for developing the oil and gas field or infrastructure. The location of the field or infrastructure may include an indication of a geographical coordinate (e.g. latitude and longitude) of the location. In an embodiment, the location of the oil and gas field or infrastructure includes an indication of whether the oil and gas field or infrastructure is associated with an onshore or an offshore development. In the present embodiment, whether the oil and gas field or infrastructure is onshore or offshore is deduced automatically by the computer system 104 based on the location of the oil and gas field or infrastructure using the database 108 or from the external database 110 via the external server 106. Provision of the location for the oil and gas field or infrastructure allows the relevant fields data, infrastructure data and environmental data associated with the location to be collated. In the present embodiment, the fields data, infrastructure data, environmental data associated with the location of the oil and gas field or infrastructure may be retrieved automatically by the computer system 104 from the database 108 or from the external database 110 via the external server 106. In an embodiment, the fields data and/or environmental data associated with the oil and gas field or infrastructure are provided as inputs by the user device 102. Other input parameters may include estimated well costs (see e.g. in relation to FIG. 12 below), manpower inputs (e.g. assignment of team members for the process of the fossil fuel operation), duration of the oil and gas field or infrastructure, cost phasing or a desired cost parameter (e.g. a desired UTC). The input parameters may also include a front-end loading (FEL) stage, where the FEL stage can be selected from one of: Pre-FEL, FEL 1, FEL 2 and FEL 3.

Descriptions of the FEL stages are as follows. The Pre-FEL or FEL 0 (Framing) relates to identification of business opportunities (idea generation phase) that may fit to business' strategic objectives. The FEL 1 (Feasibility Studies) stage relates to identification of projects that align with business objectives. This may involve selecting projects with the highest potential of meeting business objectives. The FEL 2 (Scope Selection) relates to selection of preferred process and technology options. This may include validation to ensure the projects will still meet the business objectives. The FEL 3 (Scope Definition) relates to a complete scope definition and execution plan to ensure the project will meet business objectives and can be executed with a degree of certainty. The use of the FEL stage therefore provides a handle to adjust suggested parameters, depending on a stage and/or a need of the project, for developing a set of parameters for developing an oil and gas field or infrastructure.

Non-exhaustive examples of input parameters may also include:
(i) in relation to field details of the oil and gas field or infrastructure

| Description | Details |
|---|---|
| Hydrocarbon Type | The main hydrocarbon that the oil and gas field or |
| | infrastructure is handling, could be oil or gas or both |
| | oil and gas |
| Production Life | The duration of production of the oil and gas field or |
| | infrastructure starting from the first hydrocarbon |
| | until the end of production |
| Gas Oil Ratio | A ratio of the volume of gas to the volume of oil in |
| (GOR) | relation to an output of the oil and gas field or |
| | infrastructure |
| Liquid Gas | A ratio of the volume of liquid to the volume of |
| Ratio (LGR) | gas in relation to an output of the oil and gas |
| | field or infrastructure |
| Wax appearance | The temperature at which the first wax crystals start |
| temperature | to form |
| API Gravity | A specific gravity scale developed by the American |
| | Petroleum Institute (API) for measuring a relative |
| | density of various petroleum liquids in relation to an |
| | output of the oil and gas field or infrastructure |

(ii) in relation to flowing stream properties of the oil and gas field or infrastructure

| Description | Details |
|---|---|
| CITHP (max) | The tubing head pressure when a well of the oil and |
| | gas field or infrastructure is shut in |
| FTHP (max) | The tubing head pressure when a well of the oil and |
| | gas field or infrastructure is flowing |
| FTHT (max) | The tubing head temperature when a well of the oil |
| | and gas field or infrastructure is flowing |

(iii) in relation to a number of wells of the oil and gas field or infrastructure

| Description | Details |
|---|---|
| Oil producers | The number of wells for producing oil |
| Gas producers | The number of wells for producing gas |
| Water injector | The number of wells for injecting water |
| Gas injector | The number of wells for injecting gas |

(iv) in relation to production flow rates of the oil and gas field or infrastructure

| Description | Details |
|---|---|
| Oil/Condensate | A flow rate of oil or condensate |
| Produced water | A flow rate of formation water |

(v) in relation to fluid specifications of the oil and gas field or infrastructure

| Description | Details |
|---|---|
| Carbon dioxide | The content of carbon dioxide in a well stream |
| Hydrogen sulphide | The content of hydrogen sulphide in a well stream |
| Mercury | The content of mercury in a well stream |
| Salt | The content of salt in a well stream |

(vi) in relation to enhanced recovery (input) of the oil and gas field or infrastructure

| Description | Details |
|---|---|
| Water injection | A requirement of water injection for pressure |
| | maintenance |
| Gas injection | A requirement of gas injection for pressure |
| | maintenance |
| Surface injection | An injection pressure at a surface for water or gas |
| | injection |

(vii) in relation to an artificial lift of the oil and gas field or infrastructure

| Description | Details |
|---|---|
| Gas flow rate | A flow rate of gas for gas lift purpose |
| Surface injection pressure | An injection pressure at surface for gas lift |

(viii) in relation to environment details of the oil and gas field or infrastructure

| Description | Details |
|---|---|
| Location | Physical location of the oil and gas field or |
| | infrastructure, whether it is an onshore or |
| | offshore development |
| Water depth | A depth of the water, for an offshore location |
| Ambient temperature | The highest air temperature of an environment |
| (max) | |
| Ambient temperature | The lowest air temperature of an environment |
| (min) | |
| Seabed temperature | The highest temperature of the seabed |
| (max) | |
| Seabed temperature | The lowest temperature of the seabed |
| (min) | |
| Region | An area classified based on severity of |
| | the metocean conditions |

(ix) in relation to evacuation details of the oil and gas field or infrastructure

| Description | Details |
|---|---|
| Distance | The distance of the oil or gas field or |
| | infrastructure to the evacuation point |
| Landing Pressure (Operating) | An operating pressure at the receiving |
| | facilities (set point) |
| Landing Pressure (Rated) | The designed pressure at the receiving |
| | facilities |
| LPG | Whether the export of the oil and gas |
| | field or infrastructure requires LPG |
| | as a product or not |

(x) in relation to oil export specifications for the oil and gas field or infrastructure

| Description | Details |
|---|---|
| Water Content | The content of water in the export oil |
| RVP | The measurement of volatility or tendency of a |
| | petroleum product to evaporate |
| Hydrogen Sulphide | The content of hydrogen sulphide in the export oil |
| Salt | The content of salt in the export oil |

(xi) in relation to gas export specifications for the oil and gas field or infrastructure

| Description | Details |
|---|---|
| Water Content | The content of water in the export gas |
| Carbon Dioxide | The content of carbon dioxide in the export gas |
| Hydrogen Sulphide | The content of hydrogen sulphide in the export gas |
| Mercaptan | The content of mercaptan in the export gas |
| Mercury | The content of mercury in the export gas |

In a step 304, the parameters generating module 218 is executed by the processor 202 to receive historical data associated with the plurality of input parameters. The historical data are related to processes which were previously determined or used, and serve as accurate benchmarks for subsequent generated sets of parameters for developing subsequent oil and gas fields or infrastructures. This is akin to machine learning where historical results of generated and/or determined sets of parameters for use in developing previous oil and gas fields or infrastructures can be used as basis for improving the parameters generating module 218 in generating subsequent sets of suggested parameters. The historical data may be stored as part of the parameters generating data 238 or it may be stored in the database 108. In an embodiment, the historical data associated with the plurality of input parameters includes past empirical environmental data and infrastructure data associated with a location of the oil and gas field or infrastructure.

In an embodiment, the computer system 104 is configured to request and to receive, from an empirical data server (e.g. an external server 106), empirical data associated with the location of the oil and gas field or infrastructure. The empirical data includes real-time and/or past empirical data, and/or infrastructure data associated with the location of the oil and gas field or infrastructure.

In a step 306, the parameters generating module 218 is executed by the processor 202 to generate sets of suggested parameters based on the plurality of input parameters and the historical data, each of the sets of suggested parameters includes development parameters. In the present embodiment, to generate the sets of suggested processes, the sub-modules 228, 230, 232, 234, 236 of the parameters generating module 218 are executed in sequential order. A portion of the plurality of input parameters, e.g. the type of oil and gas field or infrastructure, the location of the oil and gas field or infrastructure, the type of the oil and gas field or infrastructure, are first used by the processing design requirement sub-module 228. In the present embodiment, the processing design requirement sub-module 228 includes schemes associated with processing of oil and gas, contaminant management, recovery, evacuation models, and/or oil and gas flow assurance. Relevant outputs from the processing design requirement sub-module 228 are then inputted to the facility sizing sub-module 230. The stage parameter and the infrastructure data (e.g. retrieved in relation to the location of the oil and gas field or infrastructure) may also be included as inputs to the facility sizing sub-module 230. The facility sizing sub-module 230 includes schemes associated with sizing, a number of conductors, environmental data, well testing and facility manning. Relevant outputs from the facility sizing sub-module 230 are then inputted to the power requirement sub-module 232. The power requirement sub-module 232 includes schemes associated with a power need for the oil and gas field or infrastructure and a power generation driver for the oil and gas field or infrastructure. Relevant outputs of the power requirement sub-module 232 are then provided as inputs to the structural requirement sub-module 234. The structural requirement sub-module 234 includes schemes associated with a top-side weight of a suggested structure associated with a set of suggested parameters for the oil and gas field or infrastructure, a tree type of the structure, a host type of the structure and a facility type. Relevant outputs from the structural requirement sub-module 234 are then inputted to the pipeline sub-module 236 which includes schemes associated with pipeline needs, pipe rating, pipeline size and flowline size. The various outputs from the sub-modules 228, 230, 232, 234, 236 are then consolidated and cross-checked in generating the sets of suggested parameters having development parameters. The development parameters may comprise at least one or more of: a processing design requirement parameter, a facility sizing parameter, a power requirement parameter, a structural requirement parameter and a piping requirement parameter, where the processing design requirement parameter, the facility sizing parameter, the power requirement parameter, the structural requirement parameter and the piping requirement parameter are being generated by one of their respective sub-modules 228, 230, 232, 234, 236. Examples of a development parameter includes system listing details, a flow rate of the fossil fuel produced by the oil and gas field or infrastructure, a pressure of the piping, a weightage of the structure involved in the process, and an equipment mapping.

For example, for a topside oil and gas development, development parameters may include: manifold parameters, oil separation parameters, oil processing parameters, gas separation parameters and gas processing parameters. The manifold parameters may comprise details in relation to Christmas trees and spools, production, gas lift, gas injection, water injection, pressure protection (e.g. use of a high-integrity pressure protection system (HIPPS)), multiphase pump, multiphase metering of the topside development. The oil separation parameters may include details in relation to separation, test separator, heating (e.g. shell and tube), and plate and frame of the topside development. The oil processing parameters may include details in relation to dehydration (e.g. dehydration only or dehydration and desalting) H₂S (hydrogen sulphide) stripper, cooling (e.g. cooling of the shell and tube and/or cooling of fin fan) and the plate and frame of the topside development. The gas separation parameters may include details in relation to non-associated gas (NAG) separation and condensate stabilizer. The gas processing parameters may include details in relation to cooling (e.g. in relation to shell and tube and/or fin fan), sweetening (e.g. in relation to the solvent (amine, sulfinol, solexol) used, use of a zinc oxide vessel, use of a zinc oxide bed, use of membrane pre-treatment, a membrane system used etc.), dehydration (e.g. in relation to use of a glycol system, use of a molecular sieve vessel, use of a molecular sieve bed etc.), dew point control (e.g. in relation to low temperature separation/exchanger, refrigeration used, use of a turbo expander etc.), mercury removal, stabilizer used (e.g. in relation to liquids from hydrocarbon dew point control units (DPCU)) and gas metering.

In an embodiment where empirical data associated with the location of the oil and gas field or infrastructure was received, the sets of suggested parameters are generated taking into account the empirical data. In an embodiment, the development parameters include an estimated cost parameter. The estimated cost parameter (e.g. a UTC) may be generated using input parameters such as the duration of use in relation to the oil and gas field or infrastructure and the cost phasing for the oil and gas field or infrastructure.

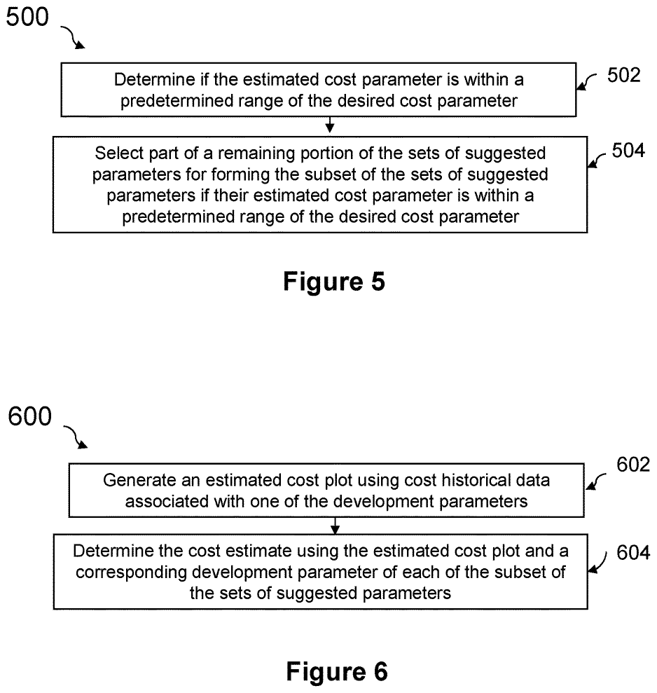

In a step 308, the parameters generating module 218 is executed by the processor 202 to form a subset of the sets of suggested parameters based on at least one of the development parameters. As there may be a large number (e.g. hundreds) of sets of suggested parameters generated in the step 306, it is desired to form a subset of the sets of suggested processes to reduce the number of sets of suggested parameters to reduce the computing power required to perform the method 300 and to enable more efficient use of computing resources. The subset of the sets of suggested parameters can be selected based on one or more steps which are discussed below in relation to FIGS. 4 and 5.

Once the subset of the sets of suggested parameters are formed in the step 308, the cost estimate module 224 is executed by the processor 202 to determine a cost estimate for each of the subset of the sets of suggested parameters in a step 310. In an embodiment, the cost estimate is determined using historical cost data associated with one of the development parameters of the subset of the sets of suggested parameters. The cost estimate may include one of: capital expenditures (CAPEX), operating expenses (OPEX) and unit technical cost (UTC) associated with the cost of developing the oil and gas field or infrastructure. Further detail of this is described in relation to FIG. 6 below. The cost estimate for each of the subset of the sets of suggested parameters are then used to determine the set of parameters for the oil and gas field or infrastructure. In an embodiment, the cost estimate for each of the subset of the sets of suggested parameters is output via the output module 208 and transmitted to the user device 102 to be presented to the user for selecting a set of parameters, among the subset of the sets of suggested parameters, for developing the oil and gas field or infrastructure.

Although the steps 302 to 310 performed by the computer system 104 as described above largely requires no human intervention once the input parameters have been received by the computer system 104, in an embodiment, the development parameters of the subset of the sets of suggested parameters as generated and/or the cost estimates of each of the subset of the sets of suggested parameters can be verified and confirmed by the user (e.g. a front-end engineer and/or a cost engineer). For example, prior to determining the cost estimate for each of the subset of the plurality of suggested parameters, the subset of the plurality of suggested parameters including their development parameters can be transmitted to the user device 102 for verification and revision (if required) before the computer system 104 perform the step 310. It should also be appreciated that outputs generated by the modules 218, 220, 222, 224, 226 and/or sub-modules 228, 230, 232, 234, 236 can be verified and revised, as necessary, by a competent user (e.g. a front-end engineer and/or a cost engineer) so as to make the method of determining a set of parameters for developing an oil and gas field or infrastructure more accurate and efficient.

FIG. 4 is a flowchart showing steps of a method 400 for determining at least some of the sets of suggested parameters to be excluded from forming a subset of the sets of suggested parameters in accordance with an embodiment. The method 400 is carried out on the computer system 104. The method 400 is used to filter out a portion of the sets of suggested parameters so that the method 300 for determining a set of parameters for an oil and gas field or infrastructure can be streamlined, saving computing resources and speeding up the method 300.

In a step 402, the parameters generating module 218 is executed by the processor 202 to assign weightages to at least some of the development parameters. The weightages of at least some of the development parameters may be received from the user device 102 or may be determined by the parameters generating module 218 based on preset logics in association with the plurality of input parameters received in the step 302.

In a step 404, the parameters generating module 218 is executed by the processor 202 to calculate a score for each of the sets of suggested parameters based on the weightages. An example for calculating a score for each of the sets of suggested parameters may include assigning scores for different ranges of values of selected development parameters, applying weightages to each of these scores, and calculating a total score for each of the sets of suggested parameters.

In a step 406, the parameters generating module 218 is executed by the processor 202 to determine at least some of the sets of suggested parameters to be excluded from forming the subset of the sets of suggested parameters for forming a remaining portion of the sets of suggested parameters, where the at least some of the sets of suggested parameters are determined to be excluded if their scores are below a predetermined score value. The predetermined score value may be preset so that the parameters generating module 218 can complete the step 406 automatically. In an embodiment, the computer system 104 prompts the user device for a filtering input to determine the predetermined score value. The parameters generating module 218 then performs the step 406 upon receiving the filtering input.

FIG. 5 is a flowchart showing steps of a method 500 for selecting a portion of the sets of suggested parameters for forming the subset of the sets of suggested parameters in accordance with an embodiment. In the present embodiment, the plurality of input parameters includes a desired cost parameter and the development parameters include an estimated cost parameter. In the present embodiment, the method 500 is used in conjunction with the method 400 to further reduce the number of sets of suggested parameters so that more relevant sets of suggested parameters can be narrowed down to form the subset of the plurality of suggested parameters. This further eases the computing resources and time required to perform the method 300 of determining a set of parameters for developing an oil and gas field or infrastructure.

In a step 502, the parameters generating module 218 is executed by the processor 202 to determine for each of the remaining portion of the sets of suggested parameters if the estimated cost parameter is within a predetermined range of the desired cost parameter. In an embodiment, the predetermined range of the desired cost parameter can be preset so that the parameters generating module 218 can complete the step 502 automatically.

In an embodiment, the computer system 104 prompts the user device 102 for a ranking input to determine the predetermined range of the desired cost parameter. The parameters generating module 218 then performs the step 502 upon receiving the ranking input.

In a step 504, the parameters generating module 218 is executed by the processor 202 to select part of the remaining portion of the sets of suggested parameters for forming the subset of the sets of suggested parameters, the part of the remaining portion of the sets of suggested parameters are selected if their estimated cost parameter is within the predetermined range of the desired cost parameter.

Although the methods 400, 500 are used in conjunction in the present embodiment, it would be appreciated that the method 400 and 500 can be used separately, independent of each other. In other words, the method 400 or the method 500 can be used independently for reducing the number of sets of suggested parameters for forming the subset of the sets of suggested parameters.

FIG. 6 is a flowchart showing steps of a method 600 for determining a cost estimate for each of the sets of suggested parameters in accordance with an embodiment.

In a step 602, the cost estimate module 224 is executed by the processor 202 to generate an estimated cost plot using historical cost data associated with one of the development parameters. The historical data is associated with actual costs for developing past oil and gas fields or infrastructures. To generate the estimated cost plot, the actual costs are plotted against one of the development parameters selected. The actual costs may be one of: capital expenditures (CAPEX), operating expenses (OPEX) and a unit technical cost (UTC). For example, a selected development parameter is a weightage of the structure involved in the oil and gas field or infrastructure. In this case, actual costs, such as CAPEX, incurred for past oil and gas fields or infrastructures are plotted against their respective weightage of the structures to generate the estimated cost plot. In an embodiment, trends can be included in the plot by modeling, for example, using a best-fit model or a regression model. It would be appreciated that one or more estimated cost plots associated with a development parameter can be generated to assist the user in an analysis of the sets of suggested parameters for determining a set of parameters for developing an oil and gas field or infrastructure. For example, a number of estimated cost plots (e.g. CAPEX, OPEX and UTC) can be generated against a selected development parameter (e.g. weightage of the structure). It would also be appreciated that one or more estimated cost plots associated with a specific cost type can be generated for a plurality of development parameters. In this case, e.g. CAPEX can be plotted against a number of selected development parameters (e.g. a weightage of the structure, a flow rate of the fossil fuel produced by the process, a pressure of the piping) to generate a number of estimated cost plots.

In a step 604, the cost estimate module 224 is executed by the processor 202 to determine the cost estimate using the estimated cost plot and a corresponding development parameter of each of the subset of the sets of suggested parameters. The cost estimate may be one of: capital expenditures (CAPEX), operating expenses (OPEX) and a unit technical cost (UTC). It would be appreciated that the cost estimate determined using the estimated cost plot would be the same as the estimated cost used. For example, if an estimated cost plot of CAPEX against weightage of the structure is used, then the cost estimate determined for each of the subset of the sets of suggested parameters is CAPEX based on the development parameter of the weightage of the structure.

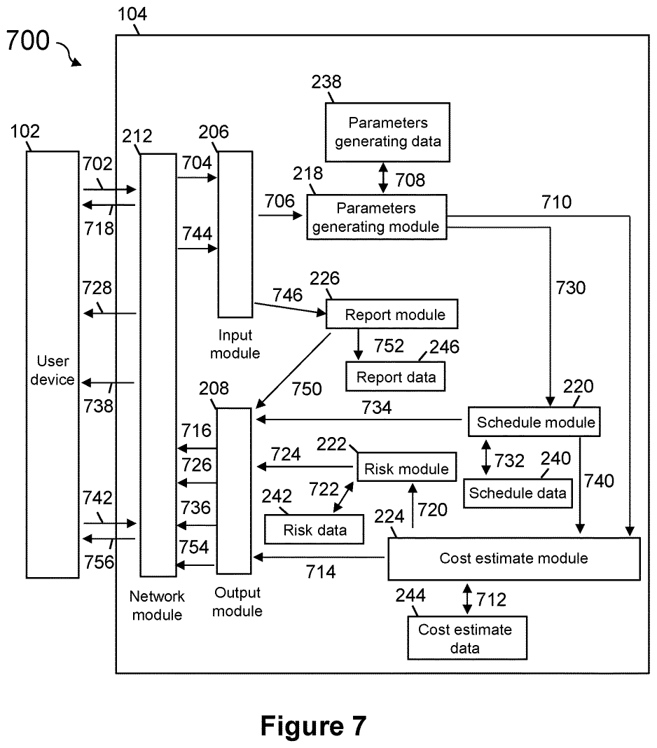

FIG. 7 shows steps of a method 700 for determining a set of parameters for developing an oil and gas field or infrastructure in accordance with an embodiment. FIG. 7 is used to illustrate a process flow of the method 300, with respect to the parameters generating module 218 and the cost estimate module 224. Methods/functions performed by the other modules 220, 222, 226 of the computer system 104 are also described in relation to FIG. 7.

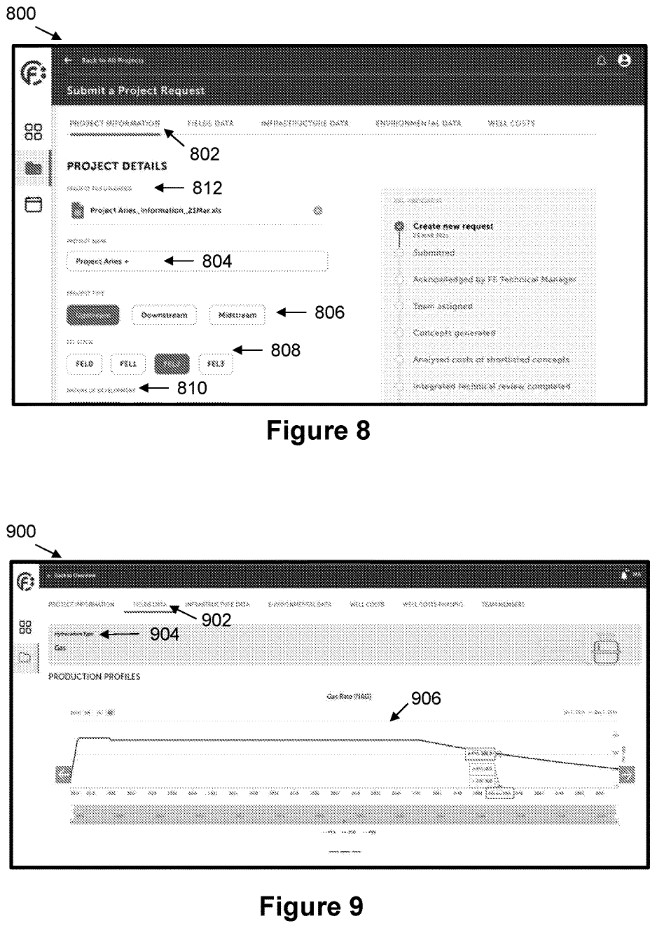

To begin the method 300 of determining a set of parameters for developing an oil and gas field or infrastructure, the user provides, via the user device 102, a plurality of input parameters to the computer system 104 via the network module 212 in a step 702. In the present embodiment, the user device 102 is connected to the computer system 104 via an internet or an intranet. The network module 212 receives the plurality of input parameters from the user device 102 and transmits the plurality of input parameters to the input module 206 in a step 704. In an embodiment, not shown in FIG. 7, the user inputs the plurality of input parameters via the user interface 210 of the computer system 104. The user interface 210 may be a graphical user interface, for example as shown below in relation to FIGS. 8 to 18, which allows the user to input selections and/or data, and it works together with the input module 206 to receive the plurality of input parameters. The plurality of input parameters comprises a type of the oil and gas field or infrastructure, a stage parameter indicating a stage of the oil and gas field or infrastructure, a type of output of the oil and gas field or infrastructure and a location of the oil and gas field or infrastructure.

In a step 706, the plurality of input parameters is transmitted to the parameters generating module 218 for processing. In a step 708, in the present embodiment, the parameters generating module 218 is configured to request and to receive historical data associated with the plurality of input parameters from the parameters generating data 238. In another embodiment, the historical data is received from the user (e.g. via an input from the user). The historical data relates to data associated with developing past oil and gas fields or infrastructures which can be used as basis for the generation of sets of suggested parameters by the parameters generating module 218. In an embodiment, the historical data includes past empirical data (e.g. past environmental data and past infrastructure data) associated with the location of the oil and gas field or infrastructure. Upon receiving the plurality of input parameters and the historical data associated with the plurality of input parameters, the parameters generating module 218 is configured to generate sets of suggested parameters based on the plurality of input parameters and the historical data. Details on the generation of the sets of suggested parameters by the parameters generating module 218 are described in relation to the step 306 of FIG. 3. Upon generating the sets of suggested parameters, the parameters generating module 218 is configured to form a subset of the sets of suggested parameters based on at least one of the development parameters. Details of forming a subset of the sets of suggested parameters are discussed in relation to FIGS. 4 and 5.

In an embodiment, the development parameters for each of the subset of the sets of suggested parameters are reviewed and checked by a user (e.g. a front-end engineer) before the cost estimate for each of the subset of the sets of suggested parameters are determined by the cost estimate module 224. In this case, though not shown in FIG. 7 for clarity, after the subset of the sets of suggested parameters are formed, the parameters generating module 218 is executed by the processor 202 to transmit the subset of the sets of suggested parameters to the user device 102, via the output module 208 and the network module 212, for verification by the user. The user may revise one or more of the development parameters of one or more sets of suggested parameters included in the subset of the sets of suggested parameters, and transmit revised or verified development parameters to the parameters generating module 218, via the network module 212 and the input module 206. The development parameters of the relevant sets of suggested parameters may be revised or updated if necessary, before the cost estimate for each of the subset of the sets of suggested parameters are determined.

Referring back to FIG. 7. Once the subset of the sets of suggested parameters are formed, the parameters generating module 218 provides outputs in relation to the subset of the sets of suggested parameters to the cost estimate module 224 in a step 710. The cost estimate module 224 is then executed by the processor 202 to determine a cost estimate for each of the subset of the sets of suggested parameters. For determining the cost estimate for each of the subset of the sets of suggested parameters, the cost estimate module 224 is executed by the processor 202 to request and to receive historical cost data associated with with one of the development parameters from the cost estimate data 244 in a step 712. The historical data is associated with actual costs for past oil and gas field or infrastructure which had been developed. Details in relation to the determination of the cost estimate are described in relation to the step 308 of FIG. 3 and the method 600 of FIG. 6. The cost estimate, together with the development parameters, of each of the subset of the sets of suggested parameters are then output via the output module in a step 714, to the network module 212 in a step 716. The subset of the sets of suggested parameters, including their corresponding development parameters and cost estimates, are then transmitted to the user device 102 by the network module 212 in a step 718. In an embodiment, where the data from the computer system 104 is shared with the user via the user interface 210, the subset of the sets of suggested parameters, including their corresponding development parameters and cost estimates, are presented to the user on the user interface 210. The information presented can then be used by the user to determine a set of parameters for developing the oil and gas field or infrastructure.

Similar to the above, in an embodiment, the cost estimate for each of the subset of the sets of suggested parameters are verified by a user (e.g. a cost engineer). This is also not shown in FIG. 7 for clarity. After the cost estimates have been determined, the cost estimate module 224 is executed by the processor 202 to transmit the cost estimates associated with the subset of the sets of suggested parameters to the user device 102, via the output module 208 and the network module 212, for checking and reviewing by the user. The user may revise one or more of the cost estimates, and transmit the revised cost estimates to the cost estimate module 224, via the network module 212 and the input module 206 to update the cost estimates for the relevant sets of suggested parameters of the subset of the sets of suggested parameters. This step of reviewing and revising the cost estimates (if necessary) may occur after the step 718 above.

Other functions of the computer system 104 in relation to other modules, for example the risk module 222, the schedule module 220, and the report module 226 are described below.

In an embodiment, the cost estimate module 224 is executed by the processor 202 to transmit the subset of the sets of suggested parameters, including their corresponding development parameters and cost estimates, to the risk module 222 in a step 720. Based on the information received from the cost estimate module 224 in relation to the subset of the sets of suggested parameters, the risk module 222 is executed by the processor 202 to perform a cost risk analysis associated with the different costs of an oil and gas field or infrastructure (e.g. location, scope, economics, commercial, interface, people, external and political) for determining uncertainties and risks associated with these different costs for each of the subset of the sets of suggested parameters. For determining the cost risk analysis, the risk module 222 is executed by the processor 202 to request and to receive risk data 242 in a step 722. The risk data 242 includes model data and/or historical data relevant for use by the risk module 222 to perform the cost risk analysis. In a step 724, risk analysis outputs associated with the cost risk analysis performed are transmitted to the output module 208. The risk analysis outputs are subsequently transmitted by the output module 208 to the network module 212 in a step 726, and transmitted by the network module 212 to the user device in a step 728. In an embodiment, a carbon footprint assessment is also executed by the processor 202 to perform carbon tax calculations and carbon abatement analysis. In this case, a sustainability report for each of the subset of the sets of suggested parameters is generated.

In a step 730, the parameters generating module 218 also provides outputs in relation to the subset of the sets of suggested parameters to the schedule module 220. The step 730 can be performed before or concurrently with the step 710. The schedule module 220 is executed by the processor 202 to generate schedules associated with the subset of the sets of suggested parameters using the outputs provided by the parameters generating module 218 in the step 730. In the present embodiment, the schedule module 220 is executed prior to the determination of a cost estimate for each of the subset of the sets of suggested parameters by the cost estimate module 224. The schedules include a timeline for completion of an oil and gas field or infrastructure and the resources required for each stage of development the oil and gas field or infrastructure. For determining the schedules, the schedule module 220 is executed by the processor 202 to request and to receive schedule data 240 in a step 732. The schedule data 240 includes model data and/or historical data in relation to past schedules generated in relation to development parameters (e.g. a weightage of a structure required for a process). In a step 734, schedule outputs associated with the generated schedules are transmitted to the output module 208. The schedule outputs are subsequently transmitted by the output module 208 to the network module 212 in a step 736, and transmitted by the network module 212 to the user device in a step 738.

Although it is described above that the cost estimate module 224, the risk module 222, and the schedule module 220 transmit their corresponding outputs to the user device 102 in separate steps, in an embodiment, at least some of these outputs can be sent to the user device 102 collectively. For example, in an embodiment, the cost estimate module 224 does not transmit its outputs to the output module 208 in the step 714. Instead, the cumulative outputs in relation to the cost estimates and the risk analysis are transmitted by the risk module 222 to the output module 208 in the step 724. In this case, the step 714 need not be performed. In an embodiment, the outputs from the schedule module 220 (e.g. schedules associated with the subset of the sets of suggested parameters) can be transmitted to the cost estimate module 224 (e.g. in a step 740), and can be taken into account for generating cost estimates by the cost estimate module 224. The various outputs from the cost estimate module 224, the risk module 222, and the schedule module 220 may be transmitted to the user device 102 for the user's review and inputs for feedbacks to the computer system 104.

Once the user has determined the set of parameters for developing the oil and gas field or infrastructure, a selection input for the determined set of parameters is received from the user device 102 at the network module 212 in a step 742. The selection input is transmitted by the network module 212 to the input module 206 in a step 744, and is subsequently transmitted to the report module 226 in a step 746. In a step 748 (not shown in FIG. 7 for clarity), the report module 226 requests and receives data in relation to the determined set of parameters, including its development parameters, cost estimate, risk analysis and schedule, from the respective cost estimate module 224, the risk module 222 and the schedule module 220. The report module 226 then generates a summary report in relation to the determined set of parameters and transmits report outputs in relation to the summary report to the output module 208 in a step 750. In the present embodiment, the report outputs are also sent to the report data 246 for storage in a step 752. The report outputs are subsequently transmitted by the output module 208 to the network module 212 in a step 754, and transmitted by the network module 212 to the user device 102 in a step 756. In the present embodiment, data in relation to progress of the development of the oil and gas field or infrastructure using the determined set of parameters can be received from the user device 102 by the report module 226, via the input module 206 and the network module 212, to track the development progress. This helps in providing live development updates of the oil and gas field or infrastructure for its relevant stakeholders.

In an embodiment, subsequent implementation results of the determined set of parameters for the oil and gas field or infrastructure are recorded and saved for use in improving the method for determining subsequent sets of parameters for developing subsequent oil and gas fields or infrastructures. In this case, the computer system 104 is configured to receive implementation results of the determined set of parameters, and transmit the implementation results to a database (e.g. the database 108 or the external database 110) for storage. The implementation results can be used to update the historical data associated with the input parameters to improve e.g. an accuracy or efficiency of the method for determining subsequent sets of parameters for developing oil and gas fields or infrastructures.

Although only one user device 102 is shown in FIG. 7, it will be appreciated that multiple user devices 102 can be in communication with the computer system 104. In this way, outputs of the computer system 104 (e.g. outputs generated by the parameters generating module 218, the cost estimate module 224, the risk module 222, the schedule module 220 and the report module 226) are accessible by different users who may be involved at different stages of the methods 300, 400, 500, 600. For example, the development parameters for each of the subset of the sets of suggested parameters can be transmitted to and reviewed by a front-end engineer, while the cost estimate for each of the subset of the sets of suggested parameters can be transmitted to and reviewed by a cost engineer. Also, although a network module 212 is used in this exemplary embodiment, it should be appreciated that a user or a plurality of users can provide inputs and/or receive outputs directly from the computer system 104 using the input module 206 and/or the output module 208 respectively.

An exemplary embodiment for determining a set of parameters for developing an oil and gas field or infrastructure is described below, in conjunction with FIGS. 8 to 18. FIGS. 8 to 18 each shows an illustration of a user interface at different stages of the method 300.

FIGS. 8 to 12 show a series of illustrations of the user interface 210 for providing input parameters to the computer system 104 of FIG. 2 in accordance with an embodiment.

FIG. 8 shows an illustration 800 of the user interface 210 for providing input parameters in relation to project information for developing an oil and gas field or infrastructure. As shown in FIG. 8, a single integrated platform is provided for submitting of a request for developing an oil and gas field or infrastructure. It also enables project data uploads and resource assignment by the user. Particularly, FIG. 8 shows a page of the project information tab 802 at a stage of creating a new request for developing an oil and gas field or infrastructure. On this page of the user interface 210, input parameters such as a name of the oil and gas field or infrastructure 804, a type of the oil and gas field or infrastructure 806, a front-end loading stage 808 and a stage of the oil and gas field or infrastructure 810 can be inputted. There is also an option 812 for uploading a file containing the relevant information of the oil and gas field or infrastructure.

FIG. 9 shows an illustration 900 of the user interface 210 for providing input parameters in relation to fields data. Particularly, FIG. 9 shows a page of the fields data tab 902 for inputting further input parameters for creating the request. On this page of the user interface 210, input parameters such as the type of output of the oil and gas field or infrastructure 904 can be introduced. FIG. 9 also shows an oil and gas production plot 906 associated with the type of output 904, which can be extracted from input data associated with the oil and gas development. The data for this plot 906 can be inputted by the user (e.g. by uploading the information at 812) or can be automatically retrieved once other relevant input parameters have been included (e.g. a location of the oil and gas field or infrastructure). The data for the plot 906 may be associated with historical production data associated with the location of the oil and gas field or infrastructure.

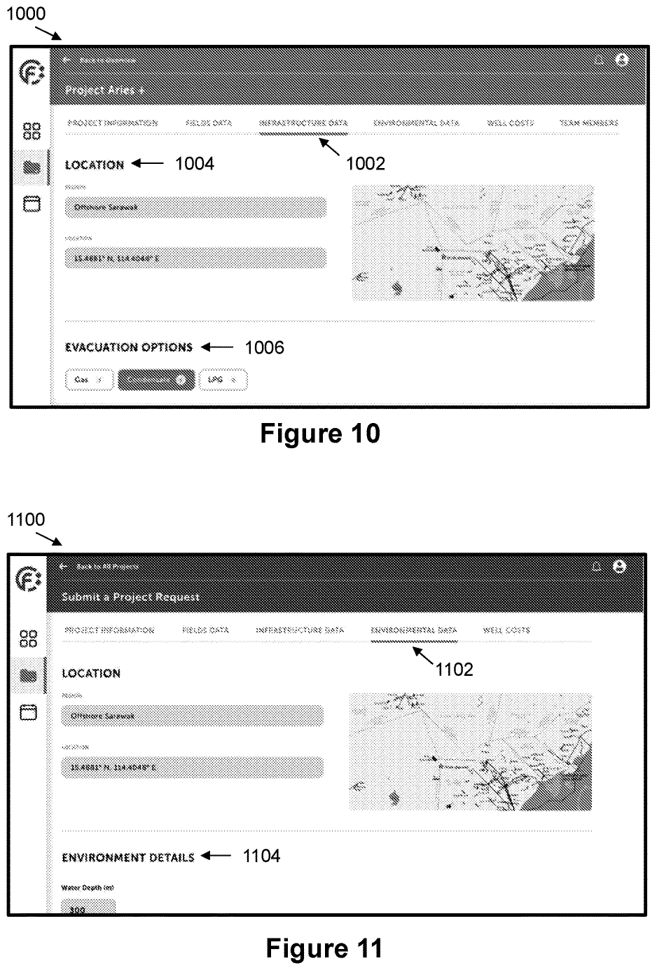

FIG. 10 shows an illustration 1000 of the user interface 210 for providing input parameters in relation to infrastructure data. Particularly, FIG. 10 shows a page of the infrastructure data tab 1002 at a stage of creating the request for developing an oil and gas field or infrastructure. On this page of the user interface 210, input parameters such as the location of the oil and gas field or infrastructure 1004 can be inputted. As shown in FIG. 10, the location of the oil and gas field or infrastructure 1004 can be specified by its region, longitude and latitude. An evacuation option 1006 can also be selected on this page as part of the input parameters. The evacuation option 1006 provides an option for selecting a suitable facility to which a hydrocarbon can be evacuated. The evacuation option 1006 will follow a hydrocarbon type (i.e. the type of output of the oil and gas field or infrastructure 904). For example, oil should be evacuated to an oil facility and gas should be evacuated to a gas facility. The infrastructure data, e.g. a region and/or location of the oil and gas development can also be extracted from the uploaded information at 812.

FIG. 11 shows an illustration 1100 of the user interface 210 for providing input parameters in relation to environmental data. Particularly, FIG. 11 shows a page of the environmental data tab 1102 for a request for developing an oil and gas field or infrastructure. On this page of the user interface 210, input parameters in relation to environment details 1104 associated with the location of the oil and gas field or infrastructure 1004 can be inputted. In an embodiment, the environment details 1104 can be automatically retrieved based on the location of the oil and gas field or infrastructure 1004. The environment details 1104 may be based on empirical, real-time environmental data associated with the location of the oil and gas field or infrastructure. Therefore, in an embodiment, the parameters generating module 218 is executed by the processor 202 to request, from an empirical data server (e.g. an external server 106), empirical data associated with the location of the oil and gas field or infrastructure. The empirical data may then be received, from the empirical data server, at the parameters generating module 218. The empirical data can include both real-time empirical data and past empirical data associated with the location of the oil and gas field or infrastructure. In an embodiment, the environmental data (e.g. water depth, ambient temperature) can be extracted from the uploaded information at 812.

FIG. 12 shows an illustration 1200 of a user interface 210 for providing input parameters in relation to well costs. The well cost inputs will be provided in accordance with different profile cases e.g., P50 and P80 which signifies a probability of success for each of these cases. As shown in FIG. 12, the well cost inputs for the P50 (i.e. 50% chance of success) case is shown in a box 1202, and the well cost inputs for the P80 (i.e. 80% chance of success) case is shown in a box 1204. Using the P50 case as an example, the well cost inputs include costs in relation to (i) costs per well 1206, (ii) mobilisation costs by location 1208 and (iii) demobilisation costs by location 1210. Also shown in this example is that the costs per well 1206 includes costs in relation to: an oil producer 1212, a water injector 1214, and a gas lift 1216. The mobilisation costs by location 1208 is associated with logistic costs for mobilising resources (e.g. man-power, equipment etc.) in relation to forming the well at the location. The demobilisation costs by location 1210 is associated with logistic costs for demobilising the resources (e.g. man-power, equipment etc.) once the well has been formed at the location. Also shown in FIG. 12, in this embodiment, the input currency 1218 can be selected to be one of Malaysian Ringgit or the U.S. dollars. This should, however, not be construed as limiting and the skilled person will appreciate that any other form of currencies may be used. In the present embodiment, the well cost inputs are inclusive of well cost phasing and/or schedule as provided by well engineers.

Once all the relevant input parameters have been received, the parameters generating module 218 is executed by the processor 202 to generate sets of suggested parameters based on the input parameters. FIG. 13 shows an illustration of a user interface 210 during generation of sets of suggested parameters for determining a set of parameters for developing an oil and gas field or infrastructure in accordance with an embodiment. During this step, the processing design requirement sub-module 228, the facility sizing sub-module 230, the power requirement sub-module 232, the structural requirement sub-module 234 and the pipeline requirement sub-module 236 of the computer system 104 are executed by the processor 202 as described above to generate the sets of suggested parameters. Each of the sets of suggested parameters generated includes development parameters. In the present embodiment, the input parameters include a desired cost parameter and the development parameters include an estimated cost parameter. The estimated cost parameter, being one of the development parameters, may be generated based on the cost-related inputs (e.g. estimated well costs etc.).

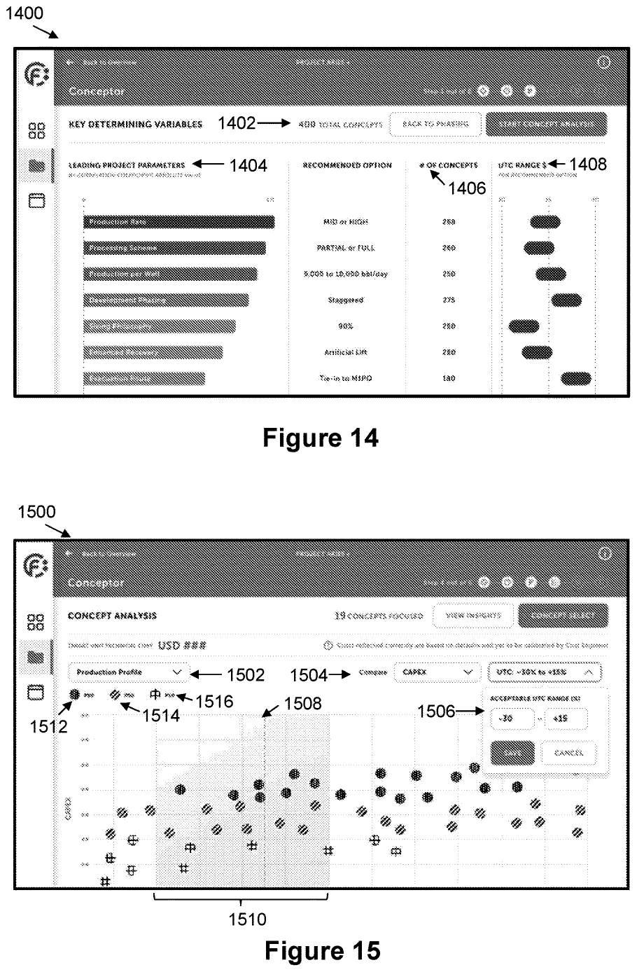

FIG. 14 shows an illustration 1400 of the user interface 210 where sets of suggested parameters are ranked according to predetermined development parameters, in accordance with an embodiment. As shown in FIG. 14, there are a total of 400 sets of suggested parameters 1402 generated in this example. The leading or predetermined development parameters 1404 for ranking the sets of suggested parameters are also shown in FIG. 14. These leading development parameters for ranking the sets of suggested parameters may be predetermined with weightages. Using the leading development parameters, the number of sets of suggested parameters can be narrowed. For example, for a leading development parameter of production rate (e.g. where it is at mid or high), the number of sets of suggested processes can be narrowed down to 288. FIG. 14 also shows an indication of a range 1408 of the estimated cost parameters associated with the narrowed down sets of parameters in relation to each of the leading parameter, with respect to the desired cost parameter. In the present embodiment, the estimated cost parameters and the desired cost parameter used relate to the UTC.

The number of sets of suggested parameters can be further narrowed by selecting sets of suggested parameters which have the estimated cost parameters fall within a specific range in relation to the desired cost parameter. FIG. 15 shows an illustration 1500 of a user interface 210 for analysing the sets of suggested parameters according to a predetermined range of a development parameter, in accordance with an embodiment. As shown in FIG. 15, the leading development parameter for forming a narrowed selection of the sets of suggested parameters can be selected using a drop-down list of leading development parameters at 1502. In the present embodiment, the leading development parameter selection is ‘production profile’. A type of the estimated cost parameter used for comparison can be selected using a drop-down list 1504. In the present embodiment, CAPEX is used for this comparison. Also shown in FIG. 15 is that an acceptable range of the desired cost parameter (in this case the UTC) can be determined to further narrowed the number of sets of suggested processes. In the present case, an acceptable UTC range 1506 of −30% of the desired UTC to +15% of the desired UTC is used. This is illustrated in FIG. 15, where a plot of CAPEX (y-axis) versus UTC (x-axis) is partially shown. The dotted line 1508 indicates an x-axis value (i.e. a UTC value) equal to the desired UTC. The highlighted portion 1510 denotes the range of UTC values within the range of −30% to +15% of the desired UTC. Each of the circle data points denotes a suggested set of parameters, and as shown in FIG. 15, each of these data points are associated with different production profile cases e.g. P90 (i.e. 90% chance of success) 1512, P50 (i.e. 50% chance of success) 1514 and P10 (i.e. 10% chance of success) 1516.

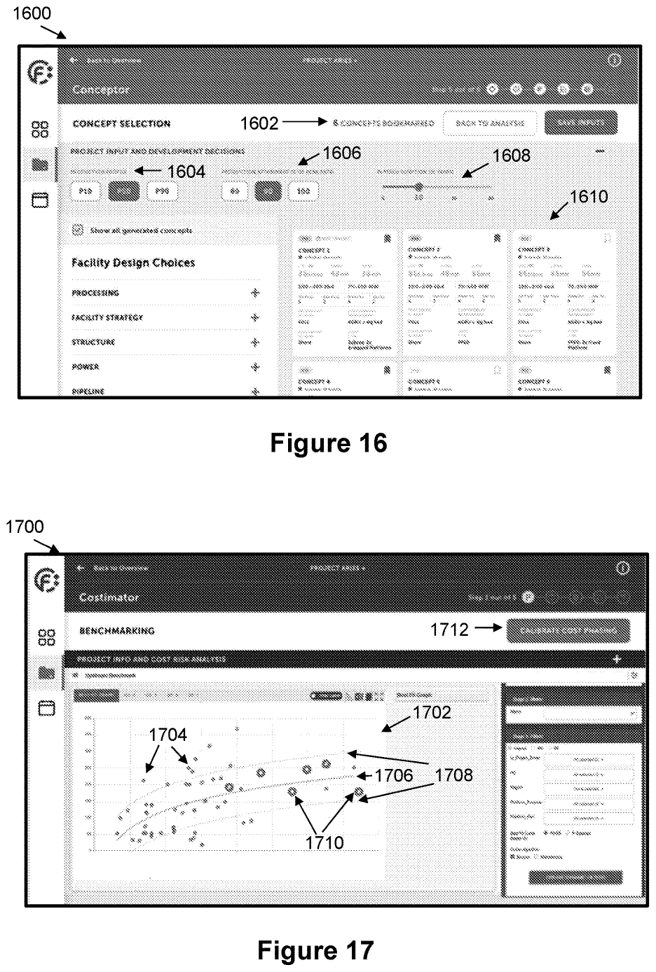

FIG. 16 shows an illustration 1600 of a user interface 210 for selecting a subset of the sets of suggested parameters in accordance with an embodiment. As shown in FIG. 16, six sets of suggested parameters 1602 have been bookmarked to form the subset of the sets of suggested parameters. FIG. 16 also shows three selection parameters which can be varied. The three selection parameters are a production profile 1604 (associated with different production profile cases with varying probability of success P10, P50 and P90), a production attainment percentage (i.e. a percentage of the peak rate attained) 1606, and a plateau duration (in years) of a production of the oil and gas field or infrastructure 1608. These three selection parameters can act as quick filters for the sets of suggested parameters. Further, FIG. 16 shows a summary for each of the six bookmarked parameters 1610. Each of the summaries as shown provide common important development parameters and may incorporate strategic reasonings for each of the subset of the sets of suggested parameters.

FIG. 17 shows an illustration 1700 of a user interface 210 for benchmarking the selected subset of the sets of suggested parameters of FIG. 16 in relation to their cost estimates in accordance with an embodiment. A graph 1702 of cost estimates (e.g. UTC) versus a selected development parameter (e.g. weightage of a structure used in the oil and gas field or infrastructure) is shown in FIG. 17. The data points 1704 as plotted in the graph 1702 are historical cost data (e.g. UTC data) for a selected development parameter (e.g. a weightage of a structure used in an oil and gas field or infrastructure). A best-fit trend for the data points 1704 are shown as 1706 with a desired band 1708 set to provide a quick indication on whether a selected set of suggested parameters fall within the desired band. The cost estimates (in this case, UTC) for each of the benchmarked suggested parameters 1710 are then estimated using the graph 1702 for a given development parameter (e.g. a weightage of a structure associated with the suggested process). FIG. 17 also shows a tab “Calibrate Cost Phasing” 1712. This allows the user to revise the cost estimates accordingly if necessary. This benchmarking as shown in FIG. 17 allows the subset of the sets of suggested parameters to be broadly tested to better ensure a feasibility, screening and selection decisions made in relation to determining the set of suggested parameters for developing the oil and gas field or infrastructure.

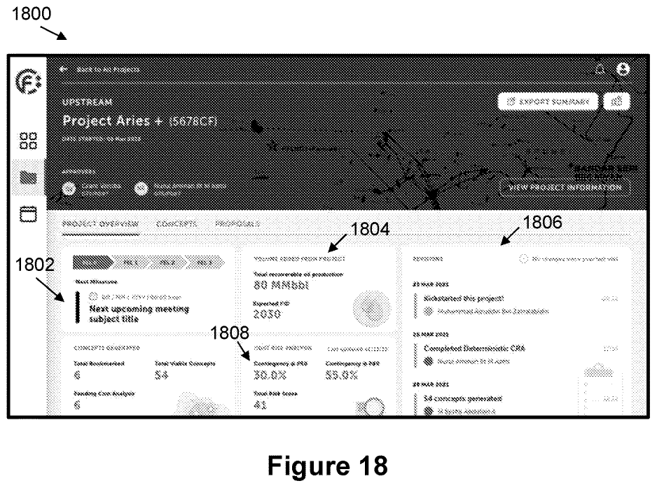

FIG. 18 shows an illustration 1800 of a user interface 210 of a summary of the results after performing the computer-implemented method for determining a set of parameters for developing an oil and gas field or infrastructure in accordance with an embodiment. As shown in FIG. 18, various panels associated with the summary of the results after performing the computer-implemented method 300 for determining the set of parameters for the oil and gas field or infrastructure are presented. This provides a collaboration work space for decision making with integrated workflow and data analysis for implement the set of parameters in developing the oil and gas field or infrastructure. For example, a panel 1802 shows a next milestone for developing the oil and gas field or infrastructure using the determined set of parameters. A panel 1804 shows a value added by developing the oil and gas field or infrastructure. A panel 1806 shows a list of updates associated with the oil and gas field or infrastructure. A panel 1808 shows a cost risk analysis for the oil and gas field or infrastructure.

Although only certain embodiments of the present invention have been described in detail, many variations are possible in accordance with the appended claims. For example, features described in relation to one embodiment may be incorporated into one or more other embodiments and vice versa.

1. A computer-implemented method for determining a set of parameters for developing an oil and gas field or infrastructure, the method comprising:
receiving a plurality of input parameters comprising a type of the oil and gas field or infrastructure, a stage parameter indicating a stage of the oil and gas field or infrastructure, a type of output of the oil and gas field or infrastructure and a location of the oil and gas field or infrastructure;
receiving historical data associated with the plurality of input parameters;
generating sets of suggested parameters for developing the oil and gas field or infrastructure based on the plurality of input parameters and the historical data, each of the sets of suggested parameters includes development parameters;
forming a subset of the sets of suggested parameters based on at least one of the development parameters; and
determining a cost estimate for each of the subset of the sets of suggested parameters for use in determining the set of parameters for developing the oil and gas field or infrastructure.

2. The method of claim 1, further comprising:
assigning weightages to at least some of the development parameters;
calculating a score for each of the sets of suggested parameters based on the weightages; and
determining at least some of the sets of suggested parameters to be excluded from forming the subset of the sets of suggested parameters to form a remaining portion of the sets of suggested parameters, the at least some of the sets of suggested parameters are determined to be excluded if their scores are below a predetermined score value.

3. The method of claim 2, wherein the plurality of input parameters includes a desired cost parameter and the development parameters include an estimated cost parameter, the method further comprising:
determining, for each of the remaining portion of the sets of suggested parameters, if the estimated cost parameter is within a predetermined range of the desired cost parameter; and
selecting part of the remaining portion of the sets of suggested parameters for forming the subset of the sets of suggested parameters, the part of the remaining portion of the sets of suggested parameters are selected if their estimated cost parameter is within a predetermined range of the desired cost parameter.

4. The method of claim 1, further comprising:
generating an estimated cost plot using historical cost data associated with one of the development parameters; and
determining the cost estimate using the estimated cost plot and a corresponding development parameter of each of the subset of the sets of suggested parameters.

5. The method of claim 1, wherein the type of the oil and gas field or infrastructure is selected from one of: an upstream oil and gas field or infrastructure, a mid-stream oil and gas field or infrastructure and a downstream oil and gas field or infrastructure, or wherein the stage parameter includes one of: greenfield, infill development and brownfield, or wherein the development parameters comprise one or more of: a processing design requirement parameter, a facility sizing parameter, a power requirement parameter, a structural requirement parameter and a piping requirement parameter.

6. (canceled)

7. The method of claim 1, further comprising:
receiving, from an empirical data server, empirical data associated with the oil and gas field or infrastructure; and
generating the sets of suggested parameters based on the empirical data.

8. (canceled)

9. The method of claim 1, wherein the historical data associated with the plurality of input parameters includes past empirical environmental data and past infrastructure data associated with the location of the oil and gas field or infrastructure.

10. The method of claim 1, further comprising:
receiving implementation results of the determined set of parameters; and
transmitting the implementation results to a database for storage, the implementation results being used to update the historical data associated with the input parameters for determination of subsequent sets of parameters for developing subsequent oil and field fields or infrastructures.

11. The method of claim 1, further comprising:
transmitting, to a user device, the subset of the sets of suggested parameters for verification of their development parameters; and
receiving, from the user device, verified development parameters for each of the subset of the sets of suggested parameters, or
transmitting, to a user device, the cost estimate of each of the subset of the sets of suggested parameters for verification; and
receiving, from the user device, a verified cost estimate for each of the subset of the sets of suggested parameters.

12. (canceled)

13. A computer readable medium storing processor executable instructions which when executed on a processor cause the processor to carry out a method according to claim 1.

14. A system for determining a set of parameters for developing an oil and gas field or infrastructure, the system comprising a processor and a data storage storing computer program instructions operable to cause the processor to:
receive a plurality of input parameters comprising of a type of the oil and gas field or infrastructure, a stage parameter indicating a stage of the oil and gas field or infrastructure, a type of output of the oil and gas field or infrastructure and a location of the oil and gas field or infrastructure;
receive historical data associated with the plurality of input parameters;
generate a set of suggested processes for developing the oil and gas field or infrastructure based on the plurality of input parameters and the historical data, each of the sets of suggested parameters includes development parameters;
form a subset of the sets of suggested parameters based on at least one of the development parameters;
determine a cost estimate for each of the subset of the sets of suggested parameters for use in determining the set of parameters for developing the oil and gas development.

15. The system of claim 14, wherein the data storage further stores computer program instructions operable to cause the processor to:
assign weightages to at least some of the development parameters;
calculate a score for each of the sets of suggested processes based on the weightages, and
determine at least some of the sets of suggested parameters to be excluded from forming the subset of the sets of suggested parameters to form a remaining portion of the sets of suggested processes, the at least some of the sets of suggested parameters are determined to be excluded if their scores are below a predetermined score value.

16. The system of claim 15, wherein the plurality of input parameters includes a desired cost parameter and the development parameters include an estimated cost parameter, the data storage further stores computer program instructions operable to cause the processor to:
determine, for each of the remaining portion of the sets of suggested parameters, if the estimated cost parameter is within a predetermined range of the desired cost parameter; and
select part of the remaining portion of the sets of suggested parameters for forming the subset of the sets of suggested parameters, the part of the remaining portion of the sets of suggested parameters are selected if their estimated cost parameter is within a predetermined range of the desired cost parameter.

17. The system of claim 14, wherein the data storage further stores computer program instructions operable to cause the processor to:
generate an estimated cost plot using historical cost data associated with one of the development parameters; and
determine the cost estimate using the estimated cost plot and a corresponding development parameter of each of the subset of the sets of suggested parameters.

18. The system of claim 14, wherein the type of the oil and gas field or infrastructure is selected from one of: an upstream oil and gas field or infrastructure, a mid-stream oil and gas field or infrastructure and a downstream oil and gas field or infrastructure, or wherein the stage parameter includes one of: greenfield, infill development and brownfield, or wherein the development parameters comprise one or more of: a processing design requirement parameter a facility sizing parameter, a power requirement parameter, a structural requirement parameter and a piping requirement parameter.

19. (canceled)

20. The system of claim 14, wherein the data storage further stores computer program instructions operable to cause the processor to:
receive, from an empirical data server, empirical data associated with the location of the oil and gas field or infrastructure; and
generate the sets of suggested parameters based on the empirical data.

21. (canceled)

22. The system of claim 14, wherein the historical data associated with the plurality of input parameters includes past empirical environmental data and past infrastructure data associated with the location of the oil and gas field or infrastructure.

23. The system of claim 14, wherein the data storage further stores computer program instructions operable to cause the processor to:
receive implementation results of the determined set of parameters; and
transmit the implementation results to a database for storage, the implementation results being used to update the historical data associated with the input parameters for determination of subsequent sets of parameters for developing subsequent oil and field fields or infrastructures.

24. The system of claim 14, wherein the data storage further stores computer program instructions operable to cause the processor to:
transmit, to a user device, the subset of the sets of suggested parameters for verification of their development parameters; and
receive, from the user device, verified development parameters for each of the subset of the sets of suggested parameters, or
transmit, to a user device, the cost estimate of each of the subset of the sets of suggested parameters for verification; and
receive, from the user device, a verified cost estimate for each of the subset of the sets of suggested parameters.

25. (canceled)

26. The system of claim 14, wherein the plurality of input parameters further comprises a front-end loading (FEL) stage, the FEL stage being selected from one of: Pre-FEL, FEL 1, FEL 2 and FEL 3.
